(19) United States
(12) Patent Application Publication
(10) Pub. No.: US 2025/0380509 A1
(43) Pub. Date: Dec. 11, 2025

(54) DISPLAY DEVICE AND MANUFACTURING METHOD THEREOF

(71) Applicant: Samsung Display Co., LTD., Yongin-si (KR)

(72) Inventors: Jong Oh SEO, Yongin-si (KR); Jae Woo JEONG, Yongin-si (KR)

(21) Appl. No.: 19/055,207

(22) Filed: Feb. 17, 2025

(30) Foreign Application Priority Data
Jun. 7, 2024 (KR) 10-2024-0074304

(51) Int. Cl. H10D 86/40; H01L 25/16; H10D 86/01; H10D 86/60

(52) U.S. Cl. CPC H10D 86/421; H01L 25/167; H10D 86/0221; H10D 86/60

(57) ABSTRACT

A display device according to an embodiment includes: a substrate; a semiconductor layer on the substrate; a gate electrode that overlaps a portion of the semiconductor layer; and a source electrode and a drain electrode electrically connected to another portion of the semiconductor layer, wherein the semiconductor layer includes a first region including polysilicon, and a second region including polysilicon and a first doping element, and the first region and the second region are provided in a thickness direction of the substrate.

### CROSS-REFERENCE TO RELATED APPLICATION

The present application claims priority to and the benefit of Korean Patent Application No. 10-2024-0074304, filed on Jun. 7, 2024, in the Korean Intellectual Property Office, the entire content of which is hereby incorporated by reference.

### BACKGROUND

### 1. Field

Embodiments of the present disclosure relate to a display device and a manufacturing method thereof.

### 2. Description of the Related Art

In general, transistors are used in many electronic device fields for a variety of purposes. For example, transistors are used as switching devices, driving devices, and photo-sensing devices, and may be used as components in various suitable electronic circuits.

### SUMMARY

Embodiments of the present disclosure provide a display device having reduced protrusions included on a polycrystalline semiconductor layer. Embodiments of the present disclosure provide a method for manufacturing a display device having reduced protrusions included on a polycrystalline semiconductor layer.

An embodiment of the present disclosure provides a display device including: a substrate; a semiconductor layer on the substrate; a gate electrode that overlaps a portion of the semiconductor layer; and a source electrode and a drain electrode electrically connected to another portion of the semiconductor layer, wherein the semiconductor layer includes a first region including polysilicon, and a second region including polysilicon and a first doping element, and the first region and the second region are provided in a thickness direction of the substrate.

The first doping element may include carbon.

Surface roughness (RMS) of an upper surface of the semiconductor layer may be about 2 nanometers to about 5 nanometers.

The first region may include the first doping element.

A content of the first doping element included the first region may be less than a content of the first doping element included in the second region.

The semiconductor layer may further include a third region in the second region, and the third region may include polysilicon and a second doping element.

The second doping element may include argon.

At least one selected from the first region and the second region may further include the second doping element.

The content of the second doping element included in at least one selected from the first region and the second region may be less than the content of the second doping element included in the third region.

The display device may further include a light emitting element electrically connected to the drain electrode.

Another embodiment of the present disclosure provides a method for manufacturing a display device including: forming an amorphous silicon layer on a substrate; forming a polysilicon layer by irradiating laser beams on the amorphous silicon layer; forming a sacrificial layer on the polysilicon layer; doping a first doping element to a first doping region including an upper region of the polysilicon layer; doping a second doping element to a second doping region on an upper side of the first doping region; and etching a portion of the sacrificial layer and the polysilicon layer.

The first doping element may include carbon.

The second doping element may include argon.

In the forming of a polysilicon layer by irradiating laser beams, the polysilicon layer may include protrusions.

The protrusions may be doped with the second doping element.

The sacrificial layer may include silicon oxide.

A thickness of the sacrificial layer may be about 500 angstroms to about 1000 angstroms.

The etching process may use a buffer oxide etchant (BOE) solution.

An etching rate of the polysilicon layer doped with the second doping element may be faster than an etching rate of the polysilicon layer doped with the first doping element.

An acceleration voltage used in a process for doping the first doping element and the second doping element may be about 20 KeV to about 40 KeV.

According to embodiments of the present disclosure, a display device in which protrusions included in a polycrystalline semiconductor layer are reduced may be provided. Further, embodiments may provide a method for manufacturing a display device that reduces protrusions in a polycrystalline semiconductor layer of the display device.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a cross-sectional view of a display device according to an embodiment.

FIG. 2 is a cross-sectional view of a semiconductor layer according to an embodiment.

FIG. 3 is a cross-sectional view of a semiconductor layer according to an embodiment.

FIG. 4 is a cross-sectional view of a semiconductor layer according to an embodiment.

Each of FIG. 5 to FIG. 15 is a cross-sectional view of a semiconductor layer generated by a manufacturing method according to an embodiment.

Each of FIG. 16 to FIG. 23 shows characteristics according to an embodiment and a comparative example.

FIG. 24 is a block diagram of an electronic device according to an embodiment.

FIG. 25 shows schematic diagrams of electronic devices according to various embodiments.

### DETAILED DESCRIPTION

The subject matter of the present disclosure will be described more fully hereinafter with reference to the accompanying drawings, in which embodiments of the disclosure are shown. As those skilled in the art would realize, the described embodiments may be modified in various suitable different ways, all without departing from the spirit or scope of the present disclosure.

Parts that are irrelevant to the description are omitted to clearly describe the subject matter of the present disclosure, and like elements are designated by like reference numerals throughout the specification.

The size and thickness of each configuration shown in the drawings may be arbitrarily shown for better understanding and ease of description, but the present disclosure is not limited thereto. In the drawings, the thicknesses of layers, films, panels, regions, etc., may be enlarged for clarity. For ease of description, the thicknesses of some layers and areas may be exaggerated.

It should be understood that if (e.g., when) an element such as a layer, film, region, or substrate is referred to as being “on” another element, it may be directly on the other element or intervening elements may also be present. In some embodiments, if (e.g., when) an element is referred to as being “directly on” another element, there are no intervening elements present. It should be understood that if (e.g., when) an element such as a layer, film, region, or substrate is referred to as being “on” another element, it can be directly on the other element or intervening elements may also be present.

Unless explicitly stated to the contrary, the words “include,” “comprise,” and variations thereof such as “includes,” “including,” “comprises,” and “comprising,” should be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

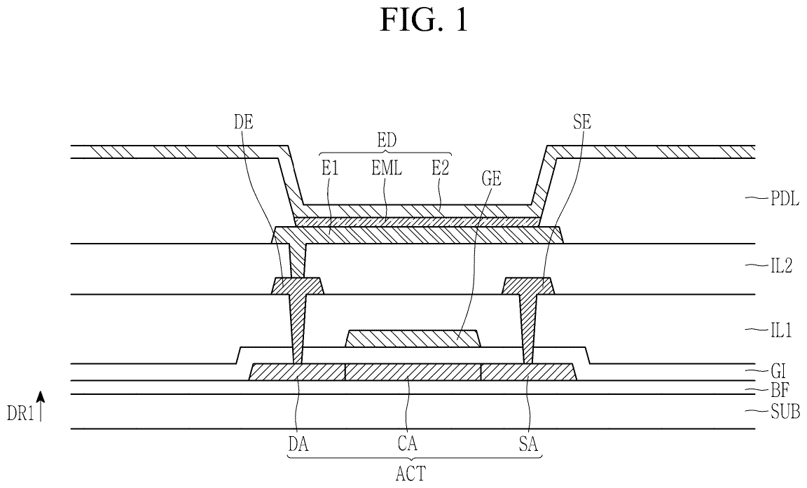

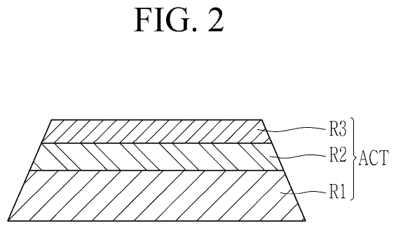

A display device according to an embodiment will now be described with reference to FIG. 1 and FIG. 2. FIG. 1 shows a cross-sectional view of a display device according to an embodiment, and FIG. 2 shows a cross-sectional view of a semiconductor layer according to an embodiment.

Referring to FIG. 1, the display device includes a substrate SUB. The substrate SUB may include a flexible material, such as plastic, that may be easily bent, folded, and/or rolled. Without being limited, the substrate SUB may include a rigid material.

A buffer layer BF may be on the substrate SUB. Depending on embodiments, the buffer layer BF may be omitted. The buffer layer BF may include silicon nitride (SiNₓ), silicon oxide (SiO₂), and/or silicon oxynitride. The buffer layer BF may be between the substrate SUB and the semiconductor layer ACT, may block impurities from the substrate SUB (e.g., to protect the substrate SUB from impurities) to improve the characteristics of polysilicon in a crystallization process of forming the polysilicon, and may planarize the substrate SUB to reduce stresses of the semiconductor layer ACT on the buffer layer BF.

The semiconductor layer ACT is on the buffer layer BF. The semiconductor layer ACT may include polysilicon. The semiconductor layer ACT includes a channel area CA, a source area SA, and a drain area DA. The source area SA and the drain area DA are on respective sides of the channel area CA.

The semiconductor layer ACT according to an embodiment will now be described in more detail with reference to FIG. 1 and FIG. 2.

The semiconductor layer ACT may include a first region R1, a second region R2, and a third region R3. The first region R1 may be provided nearest to the substrate SUB, and the second region R2 and the third region R3 may be sequentially provided on the first region R1. The first region R1, the second region R2, and the third region R3 may move away from the substrate SUB in this order.

The first region R1, the second region R2, and the third region R3 may include polysilicon. The second region R2 may further include a first doping element doped into polysilicon. The third region R3 may further include a second doping element doped into polysilicon. The first doping element may include carbon (C), and the second doping element may include argon (Ar). The first doping element and the second doping element may not change the characteristic of the semiconductor layer ACT if (e.g., when) doped into the semiconductor layer ACT.

According to an embodiment, the first region R1, the second region R2, and the third region R3 may include the first doping element. A content of the first doping element included by the first region R1 and the third region R3 according to an embodiment may be minimal, and may include very little of the first doping element. For example, the first region R1 and the third region R3 according to an embodiment may be substantially free of the first doping element such that to the extent that the first doping element is present in the first region R1 and the third region R3 it is present only as an incidental impurity. In some embodiments, the first region R1 and the third region R3 are completely free of the first doping element.

The contents of the first doping element in the first region R1, the second region R2, and the third region R3 may be different from each other. For example, the content of the first doping element in the second region R2 may be greater than the content of the first doping element in the first region R1. The content of the first doping element in the second region R2 may be greater than the content of the first doping element in the third region R3.

According to an embodiment, each of the first region R1, the second region R2, and the third region R3 may include the second doping element. The content of the second doping element in the first region R1 and the second region R2 may be minimal, and may include very little of the second doping element. For example, the first region R1 and the second region R2 according to an embodiment may be substantially free of the second doping element such that to the extent that the second doping element is present in the first region R1 and the second region R2 it is present only as an incidental impurity. In some embodiments, the first region R1 and the second region R2 are completely free of the second doping element.

The contents of the second doping element in each of the first region R1, the second region R2, and the third region R3 may be different. For example, the content of the second doping element in the third region R3 may be greater than the content of the second doping element in the second region R2. The content of the second doping element in the third region R3 may be greater than the content of the second doping element in the first region R1.

The first region R1 may include polysilicon, and may include a scarce amount of the first doping element and the second doping element. The second region R2 may include polysilicon, and may include a relatively large amount of the first doping element. The third region R3 may include polysilicon, and may include a relatively large amount of the second doping element.

An upper surface of the semiconductor layer ACT may include protrusions, or protrusions and depressions. Surface roughness (RMS) of the upper surface of the semiconductor layer ACT may be about 2 nm to about 5 nm. The semiconductor layer ACT may provide a substantially planarized upper surface. Hence, reliability of the transistor containing the semiconductor layer may be improved, and its characteristics may be improved.

Referring to FIG. 1, a gate insulating layer GI is on the semiconductor layer ACT. The gate insulating layer GI may be a single layer or a multilayer including at least one selected from among silicon nitride (SiNₓ), silicon oxide (SiO₂), and silicon oxynitride.

A gate electrode GE may be on the gate insulating layer GI, and the gate electrode GE may be a multilayer in which a metal layer including one selected from among copper (Cu), a copper alloy, aluminum (Al), an aluminum alloy, molybdenum (Mo), and a molybdenum alloy is stacked (e.g., stacked in a thickness direction DR1).

An interlayer insulating layer IL1 is on the gate electrode GE and the gate insulating layer GI. The interlayer insulating layer IL1 may include silicon nitride (SiNₓ), silicon oxide (SiO₂), and/or silicon oxynitride. Openings that expose both the source area SA and the drain area DA are provided in the interlayer insulating layer IL1.

A source electrode SE and a drain electrode DE are on the interlayer insulating layer IL1. The source electrode SE and the drain electrode DE are connected to the source area SA and the drain area DA of the semiconductor layer ACT through the openings formed in the interlayer insulating layer IL1.

A passivation layer IL2 is on the interlayer insulating layer IL1, the source electrode SE, and the drain electrode DE

The passivation layer IL2 may cover and planarize the interlayer insulating layer IL1, the source electrode SE, and the drain electrode DE, and thereby form the first electrode E1 on the passivation layer IL2 without steps (or substantially with steps, which may also be referred to as step defects). The passivation layer IL2 may be made of an organic material such as polyacrylate resin and/or polyimide resin, or a stack film of an organic material and an inorganic material.

A first electrode E1 is on the passivation layer IL2. The first electrode E1 is connected to the drain electrode DE through an opening of the passivation layer IL2.

The driving transistor configured with the gate electrode GE, the semiconductor layer ACT, the source electrode SE, and the drain electrode DE is connected to the first electrode E1 and supplies a driving current to a light emitting device ED. The display device may further include, in addition to the driving transistor shown in FIG. 1, a switching transistor connected to a data line and that transmits a data voltage in response to a scan signal, and a compensation transistor connected to the driving transistor and that compensates for a threshold voltage of the driving transistor in response to the scan signal.

A pixel defining layer PDL may be on the passivation layer IL2 and the first electrode E1, and may have a pixel opening that overlaps the first electrode E1 and defines a light emitting region. The pixel defining layer PDL may include an organic material such as polyacrylate resin and/or polyimide resin, and/or a silica-based inorganic material. The pixel opening may have a planar shape that is substantially similar to the first electrode E1, may have a rhombus shape or an octagonal shape that is similar to a rhombus in a plan view, and without being limited thereto, may have various suitable shapes such as a quadrangle or another suitable polygon.

A light emitting layer EML is on the first electrode E1 and overlaps the pixel opening. The light emitting layer EML may be made of a low-molecular organic material (e.g., a low molecular weight organic material) and/or a polymer organic material such as PEDOT (Poly 3,4-ethylenedioxythiophene). The light emitting layer EML may be a multilayer further including at least one selected from a hole injection layer (HIL), a hole transport layer (HTL), an electron transport layer (ETL), and an electron injection layer (EIL).

The light emitting layer EML may be mostly provided in the pixel opening, and may be provided laterally or above the pixel defining layer PDL.

A second electrode E2 is on the light emitting layer EML. The second electrode E2 may be on pixels, and may receive a common voltage through a common voltage transmitter of a non-display area.

The first electrode E1, the light emitting layer EML, and the second electrode E2 may configure (e.g., provide) the light emitting device ED.

The first electrode E1 may be an anode that is the hole injection electrode, and the second electrode E2 may be a cathode that is the electron injection electrode. However, the embodiment is not limited thereto, and the first electrode E1 may be a cathode and the second electrode E2 may be an anode according to an embodiment of a method of driving a display device.

Holes and electrons are injected into the light emitting layer EML from the first electrode E1 and the second electrode E2, and excitons that are a combination of the injected holes and electrons fall to the ground state from the excited state and thus emit light.

An encapsulation layer ENC is on the second electrode E2. The encapsulation layer ENC may cover the side and the upper surface of the light emitting device ED to seal a display layer.

The light emitting element is vulnerable to moisture and/or oxygen so the encapsulation layer ENC seals the display layer to block or reduce an inflow of moisture and/or oxygen from the outside. The encapsulation layer ENC may include layers, may be made of a composite film including an inorganic film and an organic film therefrom, and may be made of triple layers (e.g., three layers) in which a first inorganic film, an organic film, and a second inorganic film are sequentially formed.

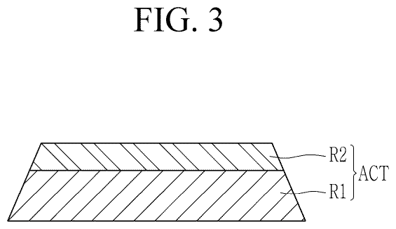

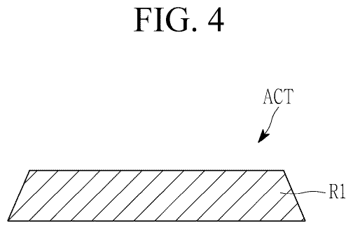

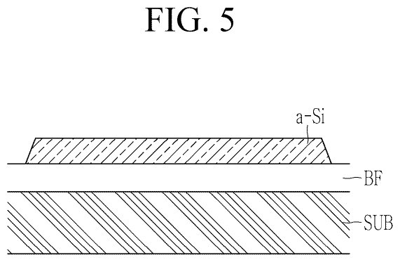

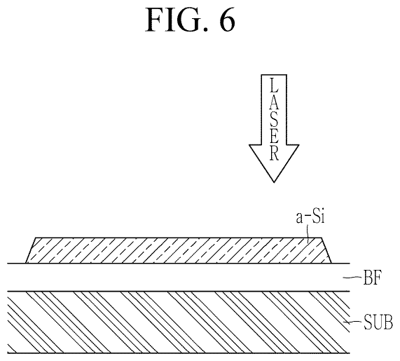

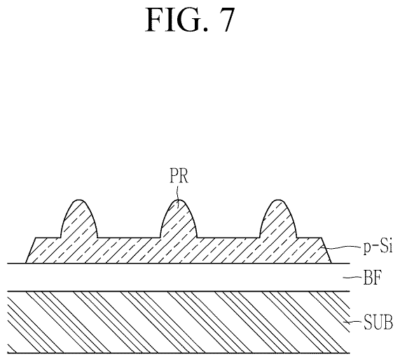

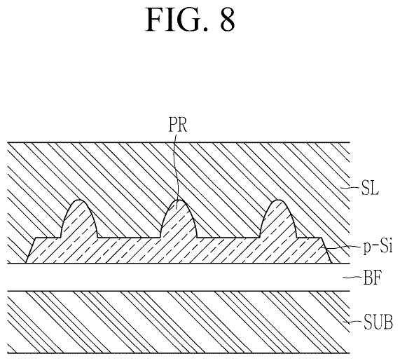

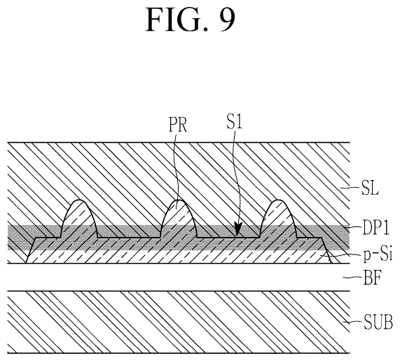

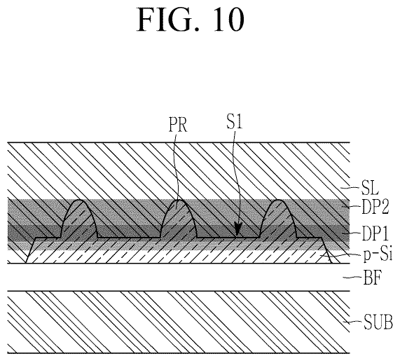

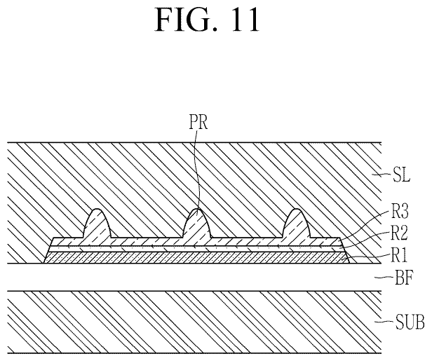

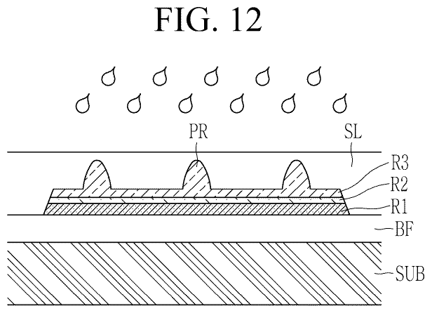

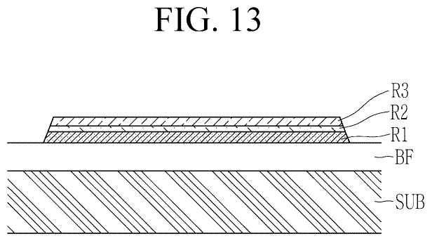

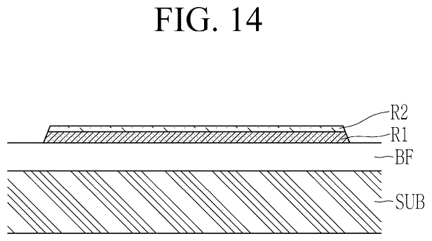

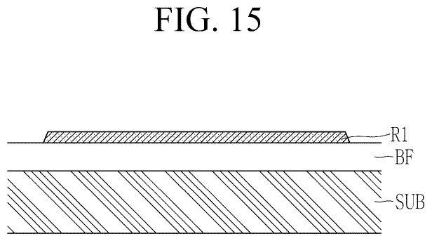

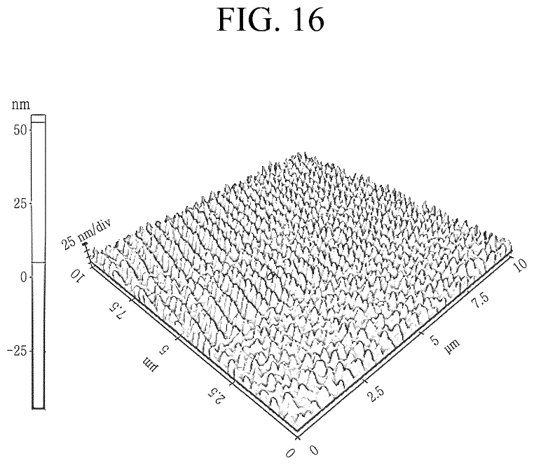

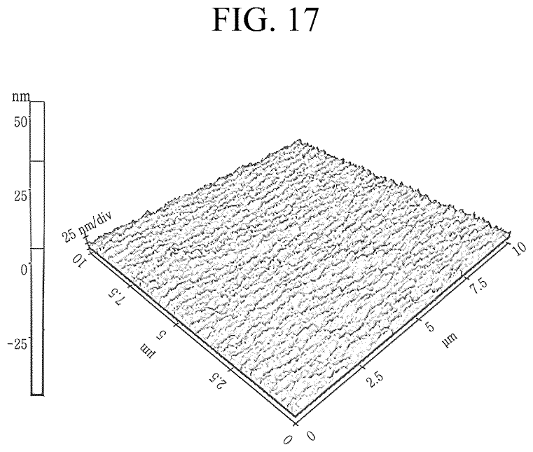

A semiconductor layer of a display device according to an embodiment will now be described with reference to FIG. 3 and FIG. 4. FIG. 3 shows a cross-sectional view of a semiconductor layer according to an embodiment, and FIG. 4 shows a cross-sectional view of a semiconductor layer according to an embodiment.

Referring to FIG. 3, the semiconductor layer ACT may include a first region R1 and a second region R2. The first region R1 may be provided nearest to the substrate SUB, and the second region R2 may be sequentially on the first region R1. The first region R1 and the second region R2 may be moved away from the substrate SUB.

The first region R1 and the second region R2 may include polysilicon. The second region R2 may further include a first doping element doped into polysilicon. The first doping element may include carbon (C). The carbon may not influence a physical property of the semiconductor layer ACT including polysilicon.

The first region R1 may further include a scarce amount of the first doping element doped into polysilicon. A scarce amount of the first doping element may remain in the first region R1 in a process for doping the first doping element into the second region R2

Depending on embodiments, the first region R1 may not include the first doping element. For example, the first region R1 according to an embodiment may be substantially free of the first doping element such that to the extent that the first doping element is present in the first region R1 it is present only as an incidental impurity. In some embodiments, the first region R1 is completely free of the first doping element. The content of the first doping element in the second region R2 may be greater than the content of the first doping element in the first region R1.

The first region R1 and the second region R2 may further include a scarce amount of the second doping element doped into polysilicon. The second doping element may be doped into a polysilicon layer during the manufacturing process, and the region to which the second doping element is doped may be removed according to the manufacturing process. However, a scarce amount of the second doping element may remain in the first region R1 and the second region R2. Depending on embodiments, the first region R1 and the second region R2 may not include the second doping element. For example, the first region R1 and the second region R2 according to an embodiment may be substantially free of the second doping element such that to the extent that the second doping element is present in the first region R1 and the second region R2 it is present only as an incidental impurity. In some embodiments, the first region R1 and the second region R2 are completely free of the second doping element.

An upper surface of the semiconductor layer ACT may include protrusions or depressions. The surface roughness (RMS) of the upper surface of the semiconductor layer ACT may be about 2 nm to about 5 nm. The semiconductor layer ACT may provide an upper surface planarized on a substantial level. Therefore, reliability of the transistor including the semiconductor layer may be improved and the characteristics may be improved.

Referring to FIG. 4, the semiconductor layer ACT may include a first region R1. The first region R1 may include polysilicon.

The first region R1 may further include a scarce amount of the first doping element doped into polysilicon. The first doping element may be doped into a portion of the polysilicon layer during the process of manufacturing a semiconductor layer, and the portion may be removed. However, a scarce amount of the first doping element may remain in the first region R1 during the process for doping a first doping element. Depending on embodiments, the first region R1 may not include the first doping element. For example, the first region R1 according to an embodiment may be substantially free of the first doping element such that to the extent that the first doping element is present in the first region R1 it is present only as an incidental impurity. In some embodiments, the first region R1 is completely free of the first doping element.

The first region R1 may further include a scarce amount of the second doping element doped into polysilicon. The second doping element may be doped into a set or predetermined region of the polysilicon layer during the process of manufacturing a semiconductor layer, and the set or predetermined region may be removed. However, a scarce amount of the second doping element may remain in the first region R1 during the process of doping the second doping element. Depending on embodiments, the first region R1 may not include the second doping element. For example, the first region R1 according to an embodiment may be substantially free of the second doping element such that to the extent that the second doping element is present in the first region R1 it is present only as an incidental impurity. In some embodiments, the first region R1 and the third region R3 are completely free of the first doping element.

The upper surface of the semiconductor layer ACT may include protrusions and/or depressions. The surface roughness (RMS) of the upper surface of the semiconductor layer ACT may be about 2 nm to about 5 nm. The semiconductor layer ACT may provide a substantially planarized upper surface. Hence, reliability of the transistor including the semiconductor layer may be improved, and the characteristics may be improved.

A method for manufacturing a semiconductor layer according to an embodiment will now be described with reference to FIG. 5 to FIG. 15. Each of FIG. 5 to FIG. 15 shows a cross-sectional view of a semiconductor layer generated by a manufacturing method according to an embodiment. The descriptions of the same configurations as those described above may not be repeated.

Referring to FIG. 5, an amorphous silicon layer (a-Si) is on the buffer layer BF. As shown in FIG. 6, laser beams are irradiated on the amorphous silicon layer (a-Si).

The amorphous silicon layer (a-Si) may be crystallized into a polysilicon layer (p-Si) according to the laser beam irradiating process, as shown in FIG. 7. The laser beam irradiating process may use instantaneous high-laser energy generated by applying a high-voltage discharge to a gas laser source, and heat-treats the amorphous silicon layer (a-Si) using laser energy. The amorphous silicon layer (a-Si) undergoes phase change from solid into liquid, and again into solid by the laser beam. Heat is discharged and the polysilicon layer (p-Si) including protrusions PR is formed in the process of undergoing a phase change from liquid to solid.

As shown in FIG. 8, a sacrificial layer SL is on the polysilicon layer (p-Si). The sacrificial layer SL may cover the upper surface of the polysilicon layer (p-Si). The upper surface of the sacrificial layer SL may be planar. The sacrificial layer SL may, for example, include a silicon oxide material.

A thickness of the sacrificial layer SL may be about 500 angstroms to about 1000 angstroms. However, the thickness is not limited thereto, and it may be changed to any suitable value of thickness to cover the upper surface of the polysilicon layer (p-Si) in a planar way and to perform an etching process.

As shown in FIG. 9, the first doping element is doped into a first doping region DP1. The first doping element may include carbon (C). The first doping region DP1 may include an upper surface S1 on which the protrusions PR are removed from the polysilicon layer (p-Si). The upper region of the polysilicon layer (p-Si) exclusive of the protrusions PR may be considered as the first doping region DP1. The first doping region DP1 may include some of the protrusions PR.

The process for doping the first doping element may be performed by using an ion implanter device. The doping process may be performed under conditions in which an acceleration voltage is about 5 KeV to about 80 KeV and a doping amount is about 1.0 E¹⁵ ion/cm² to about 1.0 E²⁰ ion/cm². Without being limited to the doping process condition, the condition of the acceleration voltage may be changed according to the thickness of the sacrificial layer SL.

If (e.g., when) doping carbon into the first doping region DP1, the carbon may reduce an etching rate in the doped first doping region DP1 in the etching process to be described.

As shown in FIG. 10, the second doping element is doped into the second doping region DP2. The second doping element may include argon (Ar). If (e.g., when) doping argon into the polysilicon, the etching rate of the polysilicon layer (p-Si) may be increased. The doping process may be performed under conditions in which the acceleration voltage is about 5 KeV to about 80 KeV and the doping amount is 1.0 E¹⁵ ion/cm² to 1.0 E²⁰ ion/cm².

The second doping region DP2 may include the protrusions PR of the polysilicon layer (p-Si). The second doping region DP2 may include a sacrificial layer SL between the adjacent protrusions PR. The second doping region DP2 may include ends of the protrusions PR.

At least portions of the first doping region DP1 and the second doping region DP2 may overlap depending on embodiments. The first doping region DP1 and the second doping region DP2 may overlap each other on the upper surface of the polysilicon layer (p-Si) exclusive of protrusions PR and the bottom surface of the protrusions PR. However, without being limited thereto, the first doping region DP1 and the second doping region DP2 may not overlap.

If (e.g., when) the doping process is performed on the first doping region DP1 and the second doping region DP2, as shown in FIG. 11, the polysilicon layer may include a first region R1 including polysilicon, a second region R2 into which the first doping element is doped, and a third region R3 into which the second doping element is doped.

However, a small or scarce amount of the first doping element may be doped into the first region R1 and the third region R3, and a small or scarce amount of the second doping element may be doped into the first region R1 and the second region R2.

As shown in FIG. 12, the etching process is performed using an etchant. The etching process may use a buffer oxide etchant (BOE). The BOE solution may be a mixed solution of 0.95% of HF and 10% of NH₄F.

As shown in FIG. 13, a portion of the sacrificial layer SL and the protrusions PR may be removed according to the etching process. In some embodiments, referring to FIG. 12, the etching rate of the third region R3 including the protrusions PR into which argon is doped into polysilicon may be relatively high. Hence, the protrusions PR may be easily etched. The etching rate of the second region R2 including polysilicon into which carbon is doped may be relatively low. Therefore, the semiconductor layer with the planar upper surface without substantial reduction of the thickness of the semiconductor layer may be provided by selectively etching the protrusions protruding from the planar upper surface. According to this, the semiconductor layer ACT as shown in FIG. 2 may be provided. In some embodiments, the thickness of the semiconductor layer may be maintained by selectively etching the protrusions.

If (e.g., when) the etching process is performed, as shown in FIG. 14, the third region R3 may be removed. According to this, as shown in FIG. 3, the semiconductor layer ACT including the first region R1 and the second region R2 may be provided.

In some embodiments, if (e.g., when) the etching process is performed, as shown in FIG. 15, the second region R2 and the third region R3 may be removed. According to some embodiments, as shown in FIG. 4, the semiconductor layer ACT including the first region R1 may be provided.

Characteristics of the semiconductor layer according to an embodiment and a comparative example will now be described with reference to FIG. 16 to FIG. 23. Each of FIG. 16 to FIG. 23 shows characteristics of the semiconductor layer according to an embodiment and a comparative example.

FIG. 16 shows an image of the semiconductor layer manufactured according to a comparative example. As the semiconductor layer manufactured according to a comparative example includes protrusions, it is found that the surface roughness value is great and a substantial amount of protrusions are formed.

FIG. 17 shows an image of the semiconductor layer manufactured according to an embodiment. According to an embodiment, the protrusions formed by the laser beam irradiating process are substantially removed (or formation of the protrusions is substantially reduced). For example, the generally planarized semiconductor layer may be provided by preventing reducing excessive etching of the polycrystalline semiconductor layer, and thereby selectively removing the protrusions (or reducing formation of the protrusions).

FIG. 18 shows an image of protrusions of the semiconductor layer manufactured according to a comparative example. The protrusions may have a height of about 1026 angstroms, and dented portions (e.g., indentations) may have a height of about 380 angstroms. FIG. 18 shows an image in which a high portion and a low portion of the semiconductor layer have a height difference of about 646 angstroms. It is found that the upper surface of the semiconductor layer is not planar but uneven.

FIG. 19 shows an image of an upper surface of the semiconductor layer manufactured according to an embodiment. Regarding the upper surface of the semiconductor layer manufactured according to an embodiment, it is found that a high portion thereof has a thickness of about 504 angstroms and a low portion thereof has a thickness of about 371 angstroms. For example, a height difference between the highest portion and the lowest portion in FIG. 19 is 133 angstroms, which is substantially reduced, compared to the comparative example of FIG. 18.

Referring to FIG. 20 to FIG. 23, FIG. 20 shows a case in which 10 KeV of argon gas is injected, FIG. 21 shows a case in which 20 KeV of argon gas is injected, FIG. 22 shows a case in which 30 KeV of argon gas is injected, and FIG. 23 shows a case in which 40 KeV of argon gas is injected.

Referring to FIG. 20, it was found that argon ions are scarcely doped into the semiconductor layer ACT and buffer layer Buffer, and are only doped into the sacrificial layer SL. Referring to FIG. 21, it was found that argon is also doped into the semiconductor layer ACT, compared to FIG. 20. It was found from FIG. 22 that argon is doped not only into the sacrificial layer SL but also into the semiconductor layer ACT, and it was found from FIG. 23 that argon is partly doped not only into the semiconductor layer ACT but also into the buffer layer Buffer. For example, it is suitable or appropriate to inject 20 KeV to 40 KeV of doping elements.

A process of etching the argon-doped polysilicon layer will now be described with reference to Table 1. The argon according to an embodiment is injected into polysilicon under the condition of 10 KeV of the acceleration voltage and 1.0 E¹⁶ ion/cm² of the doping amount.

If (e.g., when) etching the protrusions of the semiconductor layer including polysilicon by using the BOE solution similar to the comparative example, the etching rate of the sacrificial layer SL is 9.05 Å/s, and the etching rate of the semiconductor layer is about 1.66 Å/s. An etching ratio of the sacrificial layer to the semiconductor layer was found to be about 5.45.

The etching rate of the argon-doped polysilicon layer was found according to the above-described embodiment. It was found that the etching rate of the sacrificial layer SL is about 12.54 Å/s, the etching rate of the semiconductor layer is about 4.31 Å/s, and the etching ratio between the sacrificial layer and the semiconductor layer is about 2.90. For example, it was found that, as the etching rate of the argon-doped semiconductor layer by the etchant increases, an etching selecting ratio of the sacrificial layer/semiconductor layer is reduced and etching of the protrusions is advantageous or beneficial.

TABLE 1

| | | | Sacrificial |
|---|---|---|---|
| | | | layer/ |
| | Sacrificial | Semiconductor | semiconductor |
| | layer | layer | layer |
| Comparative | 9.05 | 1.66 | 5.45 |
| Example | | | |
| Embodiment | 12.54 | 4.31 | 2.90 |

An electronic device may include the display device according to embodiments of the present disclosure. The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

A display device according to an embodiment may be applied to various suitable electronic devices. An electronic device according to an embodiment may include the display device, and may further include modules or devices having additional functions other than the display device.

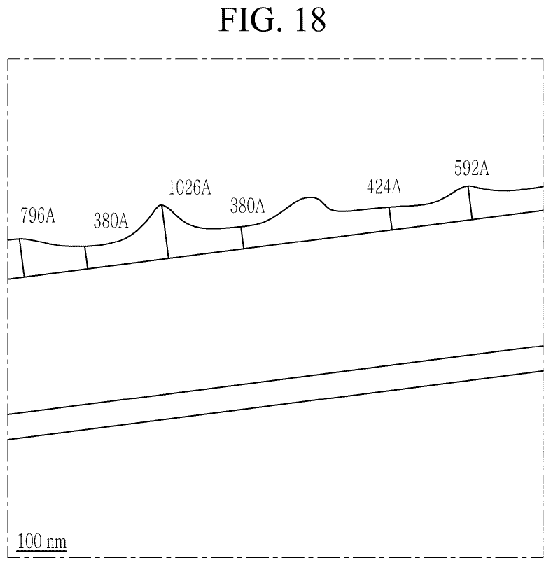

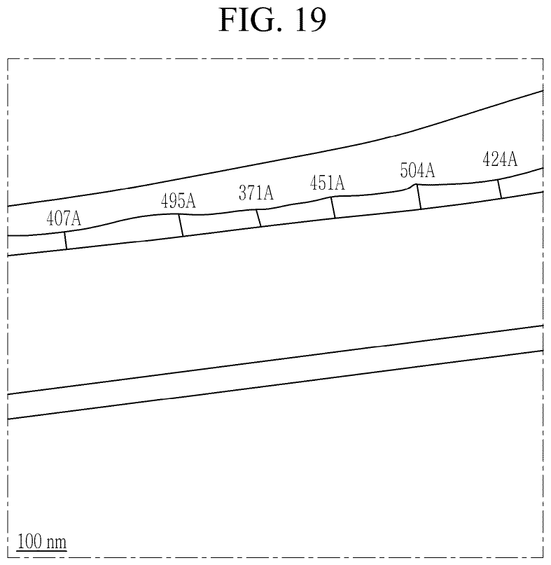

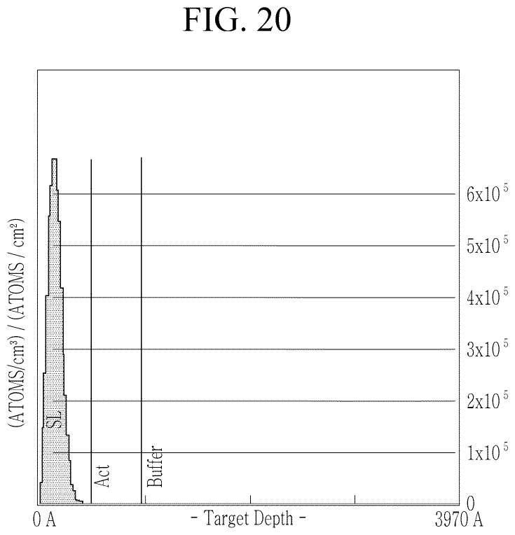

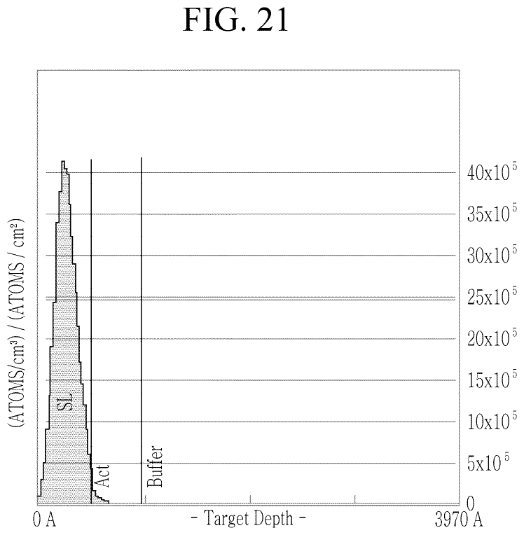

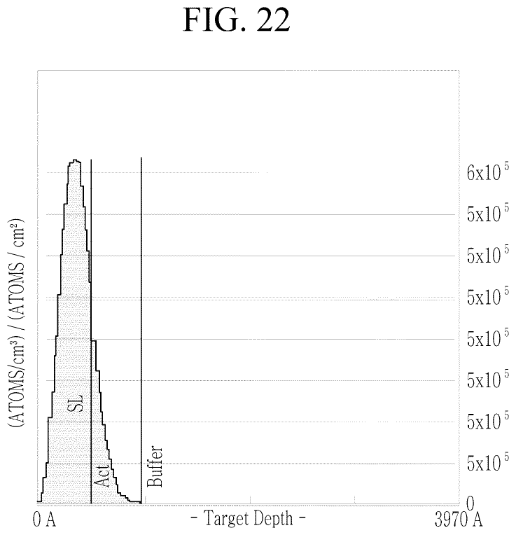

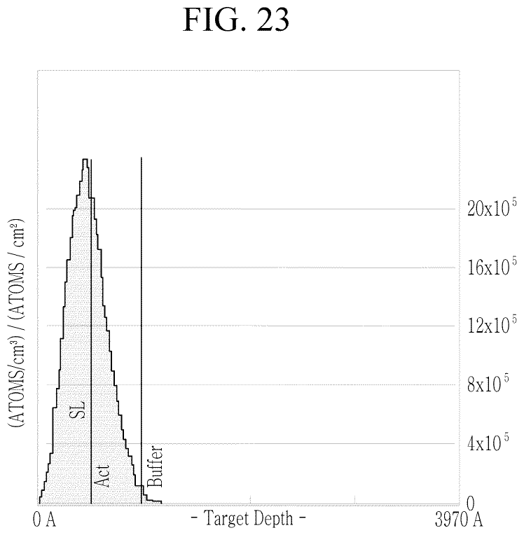

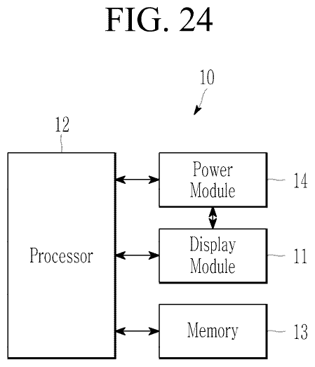

FIG. 24 is a block diagram of an electronic device according to an embodiment. Referring to FIG. 1, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

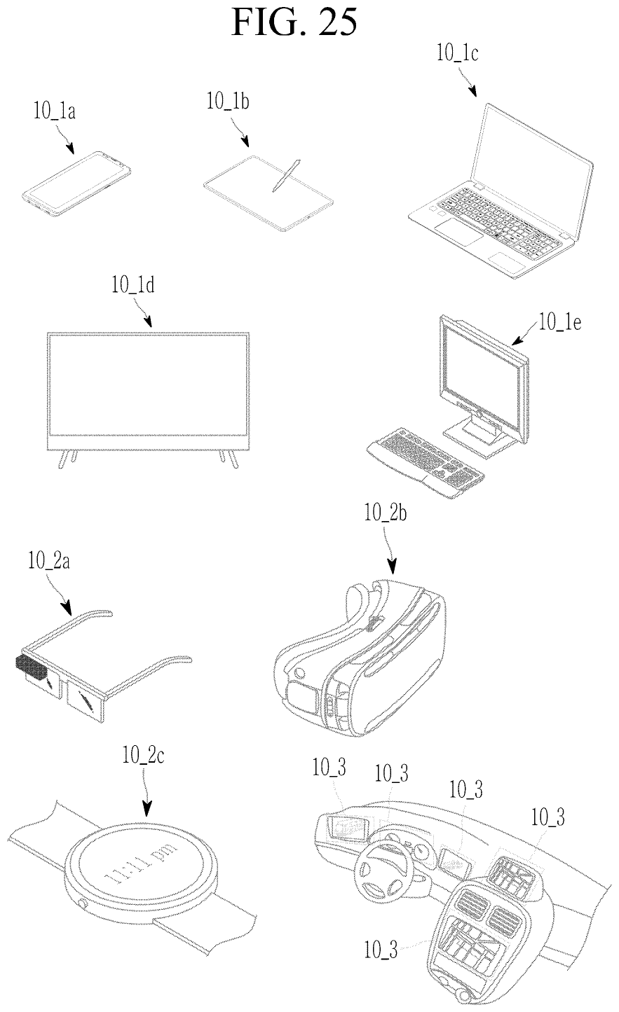

FIG. 25 shows schematic diagrams of electronic devices according to various embodiments.

Referring to FIG. 25, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

According to the above-noted embodiment, the protrusions included by the polysilicon layer may be easily removed (or formation of the protrusions may be reduced). As the semiconductor layer having a planar upper surface may be provided, reliability of the transistors may be improved, and stable display devices may be provided. While the subject matter of this disclosure has been described in connection with what is presently considered to be practical example embodiments, it is to be understood that the disclosure is not limited to the disclosed embodiments, but, on the contrary, is intended to cover various modifications and equivalent arrangements included within the spirit and scope of the appended claims, and equivalents thereof.

### DESCRIPTION OF SOME OF THE SYMBOLS

SUB: substrate
ACT: semiconductor layer
GE: gate electrode
SE: source electrode
DE: drain electrode
R1: first region
R2: second region
R3: third region

What is claimed is:

1. A display device comprising:
a substrate;
a semiconductor layer on the substrate;
a gate electrode that overlaps a portion of the semiconductor layer; and
a source electrode and a drain electrode electrically connected to another portion of the semiconductor layer,
wherein the semiconductor layer comprises:
a first region comprising polysilicon, and
a second region comprising polysilicon and a first doping element, and
the first region and the second region are provided in a thickness direction of the substrate.

2. The display device as claimed in claim 1, wherein:
the first doping element comprises carbon.

3. The display device as claimed in claim 1, wherein:
surface roughness (RMS) of an upper surface of the semiconductor layer is about 2 nanometers to about 5 nanometers.

4. The display device as claimed in claim 1, wherein:
the first region comprises the first doping element.

5. The display device as claimed in claim 4, wherein:
a content of the first doping element included in the first region is less than a content of the first doping element included in the second region.

6. The display device as claimed in claim 4, wherein:
the semiconductor layer further comprises a third region in the second region, and
the third region comprises polysilicon and a second doping element.

7. The display device as claimed in claim 6, wherein:
the second doping element comprises argon.

8. The display device as claimed in claim 6, wherein:
at least one of the first region and the second region further comprises the second doping element.

9. The display device as claimed in claim 8, wherein:
a content of the second doping element included in at least one selected from among the first region and the second region is less than a content of the second doping element included in the third region.

10. The display device as claimed in claim 1, further comprising:
a light emitting element electrically connected to the drain electrode.

11. A method for manufacturing a display device, the method comprising:
forming an amorphous silicon layer on a substrate;
forming a polysilicon layer by irradiating laser beams on the amorphous silicon layer;
forming a sacrificial layer on the polysilicon layer;
doping a first doping element into a first doping region comprising an upper region of the polysilicon layer;
doping a second doping element into a second doping region on the first doping region; and
etching a portion of the sacrificial layer and the polysilicon layer.

12. The method as claimed in claim 11, wherein:
the first doping element comprises carbon.

13. The method as claimed in claim 11, wherein:
the second doping element comprises argon.

14. The method as claimed in claim 11, wherein:
in the forming of a polysilicon layer by irradiating laser beams,
the polysilicon layer comprises protrusions.

15. The method as claimed in claim 14, wherein:
the second doping element is doped into the protrusions.

16. The method as claimed in claim 11, wherein:
the sacrificial layer comprises silicon oxide.

17. The method as claimed in claim 11, wherein:
a thickness of the sacrificial layer is about 500 angstroms to about 1000 angstroms.

18. The method as claimed in claim 11, wherein:
an etching rate of the polysilicon layer doped with the second doping element is faster than an etching rate of the polysilicon layer doped with the first doping element.

19. An electronic device comprising:
a display device comprising:
a substrate;
a semiconductor layer on the substrate;
a gate electrode that overlaps a portion of the semiconductor layer; and
a source electrode and a drain electrode electrically connected to another portion of the semiconductor layer,
wherein the semiconductor layer comprises:
a first region comprising polysilicon, and
a second region comprising polysilicon and a first doping element, and
the first region and the second region are provided in a thickness direction of the substrate.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
